(19) United States
(12) Patent Application Publication
(10) Pub. No.: US 2010/0037947 A1
(43) Pub. Date: Feb. 18, 2010

(54) Thin film type solar cell and method for manufacturing the same

(76) Inventors: Yong Hyun Lee, Seongnam-si (KR); Hyung Dong Kang, Yongin-si (KR)

Correspondence Address: Royal W. Craig;Ober, Kaler, Grimes & Shriver, 120 East Baltimore Street, Baltimore, MD, 21202-1643, US

(21) Appl. No.: 12/462,674

(22) Filed: Aug. 7, 2009

(30) Foreign Application Priority Data
Aug. 14, 2008 (KR) 10-2008-0079746

(51) Int. Cl. H01L 31/105; H01L 31/18

(52) U.S. Cl. 136/256; 438/73; 257/E31.061

(57) ABSTRACT

A thin film type solar cell and a method for manufacturing the same is disclosed, the thin film type solar cell comprising a first electrode in a predetermined pattern on a substrate; a first semiconductor layer on the first electrode; a second electrode in a predetermined pattern on the first semiconductor layer; a second semiconductor layer on the second electrode; and a third electrode in a predetermined pattern on the second semiconductor layer, the first and third electrodes being electrically connected with each other, wherein a first solar cell is composed of a combination of the first electrode, the first semiconductor layer, and the second electrode; a second solar cell is composed of a combination of the second electrode, the second semiconductor layer, and the third electrode; and the first and second solar cells are connected in parallel, whereby it is possible to realize improved efficiency of the entire thin film type solar cell without performing a process for a current matching between the first and second solar cells.

### CROSS REFERENCE TO RELATED APPLICATIONS

This application claims the benefit of the Korean Patent Application No. P2008-0079746, filed on Aug. 14, 2008, which is hereby incorporated by reference as if fully set forth herein.

### BACKGROUND OF THE INVENTION

1. Field of the Invention

The present invention relates to a solar cell, and more particularly, to a thin film type solar cell.

2. Discussion of the Related Art

A solar cell with a property of semiconductor converts a light energy into an electric energy.

A structure and principle of the solar cell according to the related art will be briefly explained as follows. The solar cell is formed in a PN-junction structure where a positive (P)-type semiconductor makes a junction with a negative (N)-type semiconductor. When a solar ray is incident on the solar cell with the PN-junction structure, holes (+) and electrons (−) are generated in the semiconductor owing to the energy of the solar ray. By an electric field generated in a PN-junction area, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

Hereinafter, a related art thin film type solar cell according to the related art will be explained with reference to the accompanying drawings.

FIG. 1(A) is a cross section view illustrating a thin film type solar cell according to one type of the related art.

As shown in FIG. 1(A), the thin film type solar cell according to one type of the related art includes a substrate 10, a front electrode layer 20, a semiconductor layer 30, and a rear electrode layer 60.

The front electrode layer 20 corresponds to a solar-ray incidence face. In this respect, the front electrode layer 20 is formed of a transparent conductive material such as ZnO.

The semiconductor layer 30 is formed of a semiconductor material such as silicon. The semiconductor layer 30 is formed in a PIN structure where a P(Positive)-type semiconductor layer, an I(Intrinsic)-type semiconductor layer, and an N(Negative)-type semiconductor layer are deposited in sequence.

The rear electrode layer 60 is formed of a metal material such as Ag or Al.

However, in case of the related art thin film type solar cell of FIG. 1(A), the semiconductor layer 30 is formed of the semiconductor material such as silicon having a low light-absorption coefficient, and the semiconductor layer 30 is formed as a thin film type having a thickness of several μm in a single PIN structure, so that it is difficult to realize the solar cell with high efficiency.

Accordingly, there has been proposed a solar cell including plural PIN structures, instead of the single PIN structure.

FIG. 1(B) is a cross section view illustrating a thin film type solar cell according to another type of the related art, which shows a tandem-structure thin film type solar cell including a semiconductor layer in which two PIN structures are deposited.

As shown in FIG. 1(B), the thin film type solar cell according to another type of the related art includes a substrate 10, a front electrode layer 20, a first semiconductor layer 30, a buffer layer 40, a second semiconductor layer 50, and a rear electrode layer 60.

Each of the first and second semiconductor layers 30 and 50 is formed in the PIN structure where a P-type semiconductor layer, an I-type semiconductor layer, and an N-type semiconductor layer are deposited in sequence. Then, the buffer layer 40 is formed between the first and second semiconductor layers 30 and 50 so as to make a smooth drift of electron and hole by a tunnel junction.

The related art thin film type solar cell of FIG. 1(B) is formed in a manner such that two solar cells are connected in series by forming the first semiconductor layer 30 of the PIN structure and the second semiconductor layer 50 of the PIN structure, thereby resulting in a high open voltage of the solar cell. Thus, in comparison to the related art thin film type solar cell of FIG. 1(A), the related art thin film type solar cell of FIG. 1(B) can accomplish the high efficiency.

However, the related art thin film type solar cell of FIG. 1(B) necessarily requires a process for a current matching between the first and second semiconductor layers 30 and 50. If the current matching is imprecise due to its fastidious process, it is impossible to accomplish the high efficiency in the solar cell.

In case of the structure where the two solar cells are connected in series, as shown in FIG. 1(B), it is necessary to perform the process for the tunneling between the first and second semiconductor layers 30 and 50 so that the electron generated in the first semiconductor layer 30 is smoothly drifted to the second semiconductor layer 50. In this case, a maximization of the tunneling secures the current matching. In order to maximize the tunneling, a thickness of the buffer layer 40 and a thickness of the P-type semiconductor layer in the second semiconductor layer 50 should be optimized. For optimizing the thickness of the buffer layer 40 and the thickness of the P-type semiconductor layer in the second semiconductor layer 50, a worker has to consume many hours in experimenting repetitively. If not obtaining the optimized results for the thickness of the buffer layer 40 and the thickness of the P-type semiconductor layer in the second semiconductor layer 50, it is impossible to accomplish the solar cell with the high efficiency due to the imprecise current matching (e.g., imbalanced currents at locations requiring accurate, matched and repeatable current sources).

### SUMMARY OF THE INVENTION

Accordingly, the present invention is directed to a thin film type solar cell and a method for manufacturing the same that substantially solves one or more problems due to limitations and disadvantages of the related art.

An object of the present invention is to provide a thin film type solar cell and a method for manufacturing the same, which is capable of realizing high efficiency without performing a process for a current matching.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a thin film type solar cell comprises a first electrode in a predetermined pattern on a substrate; a first semiconductor layer on the first electrode; a second electrode in a predetermined pattern on the first semiconductor layer; a second semiconductor layer on the second electrode; and a third electrode in a predetermined pattern on the second semiconductor layer, wherein the first and third electrodes are electrically connected with each other.

In another aspect of the present invention, a thin film type solar cell comprises a plurality of first electrodes at fixed intervals on a substrate; a first semiconductor layer on the first electrodes; a plurality of second electrodes at fixed intervals on the first semiconductor layer; a second semiconductor layer on the second electrodes; and a plurality of third electrodes at fixed intervals on the second semiconductor layer, wherein the third electrode in each unit cell is electrically connected with the first electrode in the corresponding unit cell and the second electrode in the neighboring unit cell.

In another aspect of the present invention, a method for manufacturing a thin film type solar cell comprises forming a first electrode in a predetermined pattern on a substrate; forming a first semiconductor layer on the first electrode; forming a second electrode in a predetermined pattern on the first semiconductor layer; forming a second semiconductor layer on the second electrode; forming a contact via by removing predetermined portions from the first and second semiconductor layers; and forming a third electrode in a predetermined pattern, wherein the third electrode is electrically connected with the first electrode through the contact via.

In another aspect of the present invention, a method for manufacturing a thin film type solar cell comprises forming a plurality of first electrodes at fixed intervals on a substrate; forming a first semiconductor layer on the first electrodes; forming a plurality of second electrodes at fixed intervals on the first semiconductor layer; forming a second semiconductor layer on the second electrodes; forming a contact via by removing predetermined portions from the first and second semiconductor layers; and forming a plurality of third electrodes at fixed intervals, wherein the third electrode in each unit cell is electrically connected with the first electrode in the corresponding unit cell and the second electrode in the neighboring unit cell through the contact via.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1(A) is a cross section view illustrating a thin film type solar cell according to one type of the related art, and FIG. 1(B) is a cross section view illustrating a thin film type solar cell according to another type of the related art;

FIG. 2(A) is a cross section view illustrating a thin film type solar cell according to one embodiment of the present invention, and FIG. 2(B) briefly shows a circuit structure in the thin film type solar cell of FIG. 2(A);

FIG. 3(A) and FIG. 3(B) are cross section views illustrating a thin film type solar cell according to another embodiment of the present invention;

FIG. 4(A) is a cross section view illustrating a thin film type solar cell according to another embodiment of the present invention, and FIG. 4(B) briefly shows a circuit structure in the thin film type solar cell of FIG. 4(A);

FIG. 5 is a cross section view illustrating a thin film type solar cell according to another embodiment of the present invention;

FIG. 6 is a cross section view illustrating a thin film type solar cell according to another embodiment of the present invention;

FIG. 7 is a cross section view illustrating a thin film type solar cell according to another embodiment of the present invention;

FIG. 8 (A to F) is a series of cross section views illustrating a method for manufacturing a thin film type solar cell according to one embodiment of the present invention;

FIG. 9(A to G) is a series of cross section views illustrating a method for manufacturing a thin film type solar cell according to another embodiment of the present invention; and

FIG. 10(A to F) is a series of cross section views illustrating a method for manufacturing a thin film type solar cell according to another embodiment of the present invention.

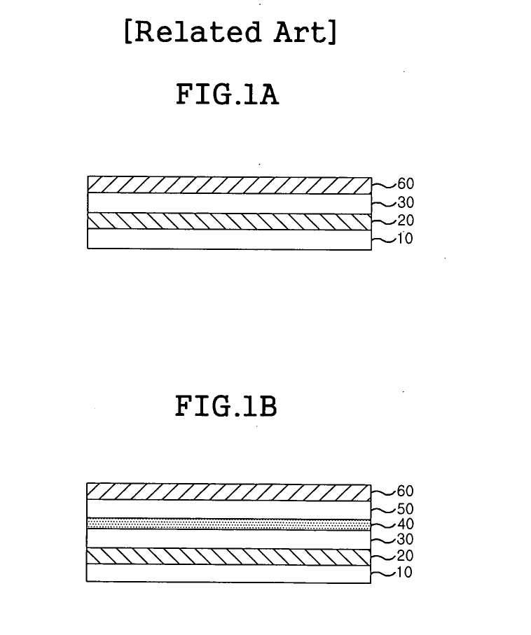

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

Thin Film Type Solar Cell

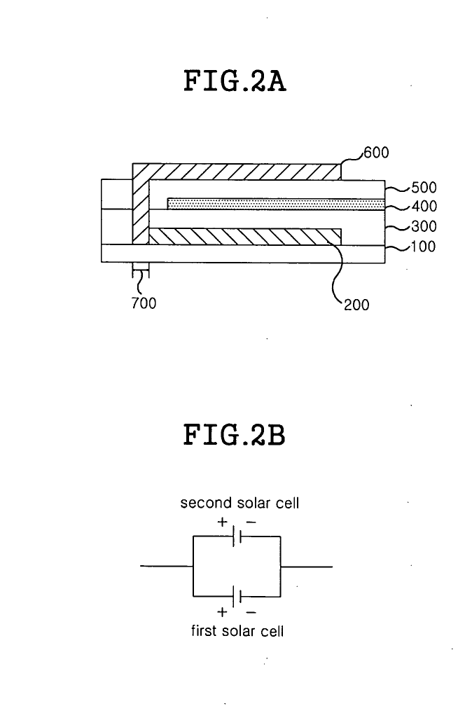

FIG. 2(A) is a cross section view illustrating a thin film type solar cell according to one embodiment of the present invention.

As shown in FIG. 2(A), the thin film type solar cell according to one embodiment of the present invention includes a substrate 100, a first electrode 200, a first semiconductor layer 300, a second electrode 400, a second semiconductor layer 500, and a third electrode 600.

The substrate 100 may be made of glass or transparent plastic.

The first electrode 200 is formed in a predetermined pattern on the substrate 100. Since the first electrode 200 corresponds to a solar-ray incidence face, the first electrode 200 is formed of a transparent conductive material, for example, ZnO, ZnO:B, ZnO:Al, SnO₂, SnO₂:F, or ITO (Indium Tin Oxide).

As the first front electrode 200 corresponds to the solar-ray incidence face, it is important for the first front electrode 200 to transmit a solar ray into the inside of the solar cell with the maximized absorption of solar ray. For this, the first front electrode 200 may have an uneven upper surface by a texturing process. The first front electrode 200 may be provided with an uneven surface, that is, a textures structure, through a known texturing process such as an etching process using photolithography, an anisotropic etching process using a chemical solution, or a mechanical scribing process. If the texturing process is applied to the first electrode 200, a solar-ray absorbing ratio on the solar cell is increased owing to a dispersion of the solar ray, thereby improving the solar cell efficiency.

The first semiconductor layer 300 is formed on the first electrode 200. Also, a contact via 700 is formed in a predetermined portion of the first semiconductor layer 300, so that the first electrode 200 and the third electrode 600 are electrically connected with each other through the contact via 700 formed in the predetermined portion of the first semiconductor layer 300.

The first semiconductor layer 300 is formed in a PIN structure where a P-type semiconductor layer, an I-type semiconductor layer, and an N-type semiconductor layer are deposited in sequence. In the first semiconductor layer 300 with the PIN structure, depletion is generated in the I-type semiconductor layer by the P-type semiconductor layer and the N-type semiconductor layer, whereby an electric field occurs therein. Thereafter, electrons and holes generated by the solar ray are drifted by the electric field. Thus, the drifted holes are collected in the first electrode 200 through the P-type semiconductor layer, and the drifted electrons are collected in the second electrode 400 through the N-type semiconductor layer.

The second electrode 400 is formed in a predetermined pattern on the first semiconductor layer 300. The second electrode 400 may be formed of a transparent conductive material, for example, ZnO, ZnO:B, ZnO:Al, SnO₂, SnO₂:F, or ITO (Indium Tin Oxide). The second electrode 400 is formed between the first electrode 200 and the third electrode 600, to thereby collect the electrons generated from the first semiconductor layer 300 and collect the electrons generated from the second semiconductor layer 500 to be described.

The second semiconductor layer 500 is formed on the second electrode 400. Also, the contact via 700 is formed in a predetermined portion of the second semiconductor layer 500, so that the first electrode 200 and the third electrode 600 are electrically connected with each other through the contact via 700 formed in the predetermined portion of the second semiconductor layer 500.

The second semiconductor layer 500 is formed in an NIP structure where an N-type semiconductor layer, an I-type semiconductor layer, and a P-type semiconductor layer are deposited in sequence. In the second semiconductor layer 500 with the NIP structure, holes generated by the solar ray are collected in the third electrode 600 through the P-type semiconductor layer, and electrons are collected in the second electrode 400 through the N-type semiconductor layer.

In the meantime, the first semiconductor layer 300 may be formed of an amorphous semiconductor material of PIN structure, and the second semiconductor layer 500 may be formed of a microcrystalline semiconductor material of NIP structure.

While the amorphous semiconductor material absorbs the solar ray with a short wavelength, the microcrystalline semiconductor material absorbs the solar ray with a long wavelength. When combining the amorphous semiconductor material with the microcrystalline semiconductor material, light absorption efficiency can be improved. Also, if the amorphous semiconductor material is exposed to light for a long period of time, it may have a problem such as an accelerated deterioration. Thus, when the amorphous semiconductor material is formed on the solar-ray incidence face, the microcrystalline semiconductor material is formed above the amorphous semiconductor material, to thereby prevent the amorphous semiconductor material from being deteriorated. However, it is not limited to this. For instance, the first and second semiconductor layer 300 and 500 may vary in material, that is, the first semiconductor layer 300 may be formed of amorphous semiconductor/germanium or microcrystalline semiconductor, and the second semiconductor layer 500 may be formed of amorphous semiconductor or amorphous semiconductor/germanium.

Also, the first semiconductor layer 300 may be formed in the NIP structure where the N-type semiconductor layer, the I-type semiconductor layer, and the P-type semiconductor layer are deposited in sequence; and the second semiconductor layer 500 may be formed in the PIN structure where the P-type semiconductor layer, the I-type semiconductor layer, and the N-type semiconductor layer are deposited in sequence. In this case, the holes generated by the solar ray are collected in the second electrode 400 through the P-type semiconductor layer, and the electrons are collected in the first and third electrodes 200 and 600 through the N-type semiconductor layer.

The third electrode 600 is formed in a predetermined pattern on the second semiconductor layer 500, and is connected with the first electrode 200 through the contact via 700 formed in the first and second semiconductor layers 300 and 500. The third electrode 600 may be formed of a metal material, for example, Ag, Al, Ag+Mo, Ag+Ni, or Ag+Cu.

In the thin film type solar cell according to one embodiment of the present invention, a first solar cell is composed of a combination of the first electrode 200, the first semiconductor layer 300, and the second electrode 400, a second solar cell is composed of a combination of the second electrode 400, the second semiconductor layer 500, and the third electrode 600. Also, the first electrode 200 and the third electrode 600 are connected with each other. Thus, the first and second solar cells are connected in parallel, as shown in FIG. 2(B). Accordingly, there is no requirement for a process for a current matching between the first and second solar cells.

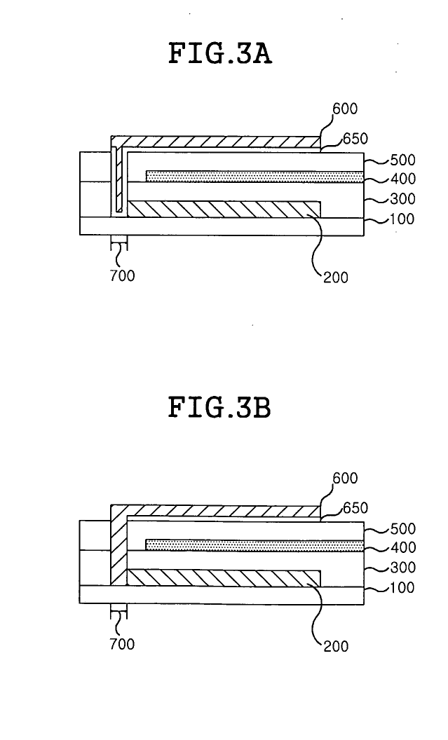

FIG. 3(A) and FIG. 3(B) are cross section views illustrating a thin film type solar cell according to another embodiment of the present invention. This embodiment is similar to that of FIG. 2(A) except that a transparent conductive layer 650 is additionally formed under a lower surface of a third electrode 600. Otherwise, the thin film type solar cell of FIG. 3(A) and FIG. 3(B) is identical in structure to the aforementioned thin film type solar cell of FIG. 2(A). Accordingly, the same reference numbers will be used throughout the drawings to refer to the same or like parts, and a detailed explanation for the same parts will be omitted.

As shown in FIG. 3(A), the transparent conductive layer 650 is formed on an upper surface of a second semiconductor layer 500, and is connected with a first electrode 200 through a contact via 700 formed in first and second semiconductor layers 300 and 500. In this case, the third electrode 600 is electrically connected with the first electrode 200 through the transparent conductive layer 650.

As shown in FIG. 3(B), the transparent conductive layer 650 may be formed only on the upper surface of the second semiconductor layer 500 without being formed inside the contact via 700.

The transparent conductive layer 650 may be formed of a material such as ZnO, ZnO:B, ZnO:Al, SnO₂, SnO₂:F, or ITO (Indium Tin Oxide).

The transparent conductive layer 650 makes the solar ray dispersed in all angles, whereby the solar ray is reflected on the third electrode 600 and is then re-incident on the solar cell, thereby resulting in the improved efficiency of solar cell.

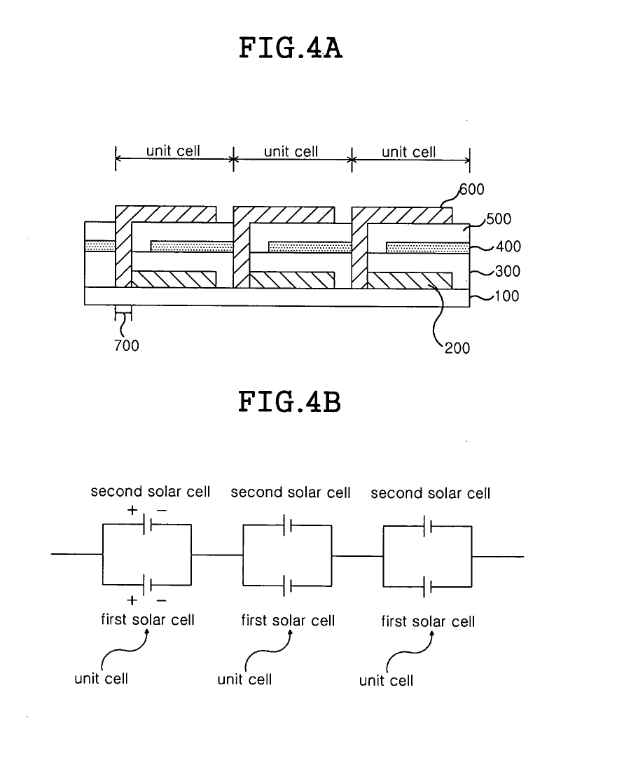

FIG. 4(A) is a cross section view illustrating a thin film type solar cell according to another embodiment of the present invention, which is made by connecting a plurality of unit cells in series, wherein each unit cell comprises a thin film type solar cell structure as in FIG. 2(A). Accordingly, the same reference numbers will be used throughout the drawings to refer to the same or like parts, and a detailed explanation for the same parts will be omitted.

As shown in FIG. 4(A), the thin film type solar cell according to another embodiment of the present invention includes a substrate 100, a first electrode 200, a first semiconductor layer 300, a second electrode 400, a second semiconductor layer 500, and a third electrode 600.

The plurality of first electrodes 200 are formed at fixed intervals on the substrate 100.

The first semiconductor layer 300 is formed on the first electrodes 200. Also, a contact via 700 is formed in a predetermined portion of the first semiconductor layer 300, so that the first electrode 200 and the third electrode 600 are electrically connected with each other through the contact via 700 formed in the predetermined portion of the first semiconductor layer 300.

The plurality of second electrodes 400 are formed at fixed intervals on the first semiconductor layer 300.

The second semiconductor layer 500 is formed on the second electrodes 400. Also, a contact via 700 is formed in a predetermined portion of the second semiconductor layer 500, so that the first electrode 200 and the third electrode 600 are electrically connected with each other through the contact via 700 formed in the predetermined portion of the second semiconductor layer 500.

If the first semiconductor layer 300 is formed in a PIN structure where a P-type semiconductor layer, an I-type semiconductor layer, and an N-type semiconductor layer are deposited in sequence, the second semiconductor layer 500 is formed in an NIP structure where the N-type semiconductor layer, the I-type semiconductor layer, and the P-type semiconductor layer are deposited in sequence. In the meantime, if the first semiconductor layer 300 is formed in the NIP structure where the N-type semiconductor layer, the I-type semiconductor layer, and the P-type semiconductor layer are deposited in sequence, the second semiconductor layer 500 is formed in the PIN structure where the P-type semiconductor layer, the I-type semiconductor layer, and the N-type semiconductor layer are deposited in sequence.

The plurality of third electrodes 600 are formed at fixed intervals on the second semiconductor layer 500. Each third electrode 600 is connected with the first electrode 200 in the corresponding unit cell through the contact via 700 formed in the first and second semiconductor layers 300 and 500, and is also connected with the second electrode 400 in the neighboring unit cell.

The thin film type solar cell according to another embodiment of the present invention has the following structural features.

First, each of the plurality of unit cells is comprised of first and second solar cells, wherein the first solar cell is composed of a combination of the first electrode 200, the first semiconductor layer 300, and the second electrode 400; the second solar cell is composed of a combination of the second electrode 400, the second semiconductor layer 500, and the third electrode 600; and the first and second solar cells are connected in parallel by connecting the first and third electrodes 200 and 600 with each other, as shown in FIG. 4(B). Accordingly, there is no requirement for a process for a current matching between the first and second solar cells.

Second, inasmuch as the third electrode 600 in each of the unit cells is connected with the second electrode 400 in the neighboring unit cell, as shown in FIG. 4(B), the plurality of unit cells are connected in series. Accordingly, even though the substrate increases in size, it is possible to decrease a size of the electrode, thereby preventing the increase of electrode resistance.

Although not shown, the thin film type solar cell of FIG. 4(A) may have an additional transparent conductive layer formed under a lower surface of the third electrode 600. The structure of the transparent conductive layer can be easily understood with reference to the transparent conductive layer 650 formed in the thin film type solar cell of FIG. 3(A) and FIG. 3(B).

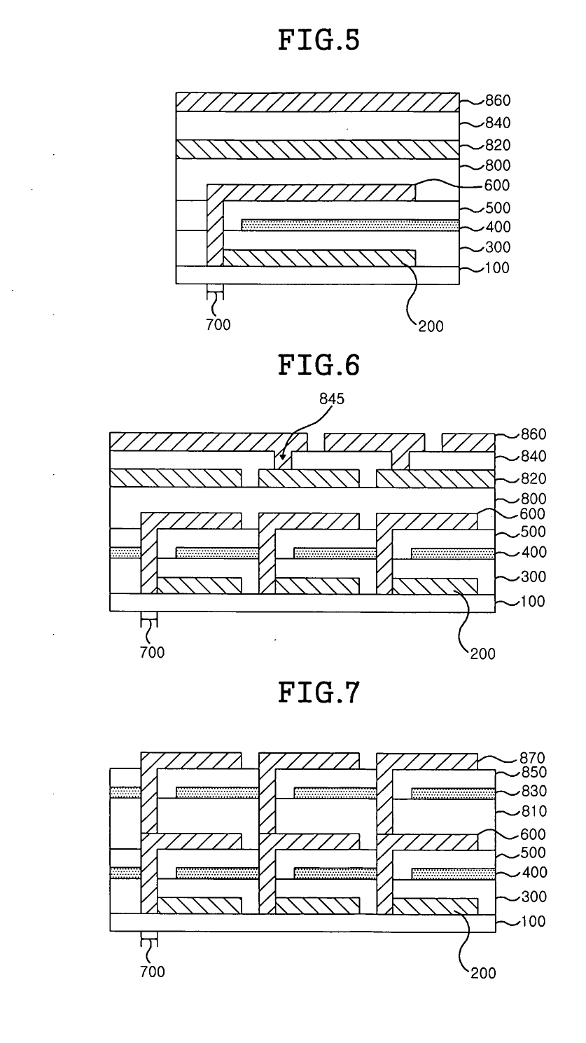

FIG. 5 is a cross section view illustrating a thin film type solar cell according to another embodiment of the present invention, which is made by providing an additional solar cell on the thin film type solar cell of FIG. 2(A). Accordingly, the same reference numbers will be used throughout the drawings to refer to the same or like parts, and a detailed explanation for the same parts will be omitted.

As shown in FIG. 5, an insulating layer 800 is formed on the aforementioned thin film type solar cell of FIG. 2(A), that is, the insulating layer 800 is formed on third electrode 600. Then, a fourth electrode 820 is formed on the insulating layer 800, a third semiconductor layer 840 is formed on the fourth electrode 820, and a fifth electrode 860 is formed on the third semiconductor layer 840. Thus, a third solar cell is composed of a combination of the fourth electrode 820, the third semiconductor layer 840, and the fifth electrode 860.

In order to smoothly transmit the incident solar ray from a lower side of the solar cell to the third solar cell, the third electrode 600 is preferably formed of a transparent conductive material. Preferably, the insulating layer 800 is formed of a transparent insulating material, for example, SiO₂, TiO₂, SiNₓ, or SiON, and the fourth electrode 820 is formed of the transparent conductive material.

The third semiconductor layer 840 may be formed in a PIN structure or NIP structure. The fifth electrode 860 may be formed of a metal material, for example, Ag, Al, Ag+Mo, Ag+Ni, or Ag+Cu.

FIG. 6 is a cross section view illustrating a thin film type solar cell according to another embodiment of the present invention, which is made by providing an additional solar cell on the thin film type solar cell of FIG. 4(A). Accordingly, the same reference numbers will be used throughout the drawings to refer to the same or like parts, and a detailed explanation for the same parts will be omitted.

As shown in FIG. 6, an insulating layer 800 is formed on the aforementioned thin film type solar cell of FIG. 4(A), that is, the insulating layer 800 is formed on third electrode 600. Then, a fourth electrode 820 is formed on the insulating layer 800, a third semiconductor layer 840 is formed on the fourth electrode 820, and a fifth electrode 860 is formed on the third semiconductor layer 840. Thus, a third solar cell is composed of a combination of the fourth electrode 820, the third semiconductor layer 840, and the fifth electrode 860.

In order to smoothly transmit the incident solar ray from a lower side of the solar cell to the third solar cell, the third electrode 600 is preferably formed of a transparent conductive material. Preferably, the insulating layer 800 is formed of a transparent insulating material, for example, SiO₂, TiO₂, SiNₓ, or SiON.

The plurality of fourth electrodes 820 are formed of the transparent conductive material. Also, the plurality of fourth electrodes 820 are formed at fixed intervals.

The third semiconductor layer 840 may be formed in a PIN structure or NIP structure. Also, a contact via 845 is formed in a predetermined portion of the third semiconductor layer 840.

The plurality of fifth electrodes 860 are formed at fixed intervals, wherein the plurality of fifth electrodes 860 are formed of a metal material, for example, Ag, Al, Ag+Mo, Ag+Ni, or Ag+Cu. Also, the fifth electrode 860 in each unit cell is electrically connected with the fourth electrode 820 in the neighboring unit cell through the contact via 845.

According to FIG. 6, the plurality of unit cells are connected in series, wherein each unit cell corresponds to the third solar cell which is composed of a combination of the fourth electrode 820, the third semiconductor layer 840, and the fifth electrode 860.

FIG. 7 is a cross section view illustrating a thin film type solar cell according to another embodiment of the present invention, which is made in a double-layered structure, each layer comprised of the thin film type solar cell of FIG. 4(A). Accordingly, the same reference numbers will be used throughout the drawings to refer to the same or like parts, and a detailed explanation for the same parts will be omitted.

As shown in FIG. 7, a third semiconductor layer 810 is formed on a third electrode 600, a fourth electrode 830 is formed on the third semiconductor layer 810, a fourth semiconductor layer 850 is formed on the fourth electrode 830, and a fifth electrode 870 is formed on the fourth semiconductor layer 850.

In order to smoothly transmit the incident solar ray from a lower side of the solar cell to an upper portion of the solar cell, the third electrode 600 is formed of a transparent conductive material, preferably.

Then, a contact via 700 is formed in predetermined portions of the third and fourth semiconductor layers 810 and 850, so that the third and fifth electrodes 600 and 870 can be electrically connected with each other through the contact via 700 formed in the predetermined portions of the third and fourth semiconductor layers 810 and 850.

The fourth electrode 830 is formed of a transparent conductive material, for example, ZnO:B, ZnO:Al, SnO₂, SnO₂:F, or ITO (Indium Tin Oxide). Also, the fourth electrode 830 collects electrons or holes generated in the third and fourth semiconductor layers 810 and 850. The fourth electrode 830 in each unit cell is connected with the fifth electrode 870 in the neighboring unit cell, to thereby connect the plurality of unit cells in series.

The fifth electrode 870 is formed of a metal material, for example, Ag, Al, Ag+Mo, Ag+Ni, or Ag+Cu. The fifth electrode 870 is connected with the third electrode 600 through the contact via 700 formed in the third and fourth semiconductor layers 810 and 850.

In the thin film type solar cell of FIG. 7, a first solar cell is composed of a combination of the first electrode 200, the first semiconductor layer 300, and the second electrode 400; a second solar cell is composed of a combination of the second electrode 400, the second semiconductor layer 500, and the third electrode 600; a third solar cell is composed of a combination of the third electrode 600, the third semiconductor layer 810, and the fourth electrode 830; and a fourth solar cell is composed of a combination of the fourth electrode 830, the fourth semiconductor layer 850, and the fifth electrode 870.

In the thin film type solar cell of FIG. 7, on assumption that the first semiconductor layer 300 is formed in a PIN structure; the second semiconductor layer 500 is formed in an NIP structure, the third semiconductor layer 810 is formed in the PIN structure, and the fourth semiconductor layer 850 is formed in the NIP structure. Thus, the electrons generated by the solar ray are collected in the second and fourth electrodes 400 and 830, and the holes generated by the solar ray are collected in the first, third, and fifth electrodes 200, 600, and 870. On assumption that the first semiconductor layer 300 is formed in the NIP structure; the second semiconductor layer 500 is formed in the PIN structure, the third semiconductor layer 810 is formed in the NIP structure, and the fourth semiconductor layer 850 is formed in the PIN structure. In this case, the holes generated by the solar ray are collected in the second and fourth electrodes 400 and 830, and the electrons generated by the solar ray are collected in the first, third, and fifth electrodes 200, 600, and 870. As mentioned above, the thin film type solar cell of FIG. 7 is formed in the double-layered structure, wherein each layer is comprised of the thin film type solar cell of FIG. 4(A). However, it is not limited to this, that is, it may have a three-layered structure, each layer having the thin film type solar cell of FIG. 4(A).

Method for Manufacturing Thin Film Type Solar Cell

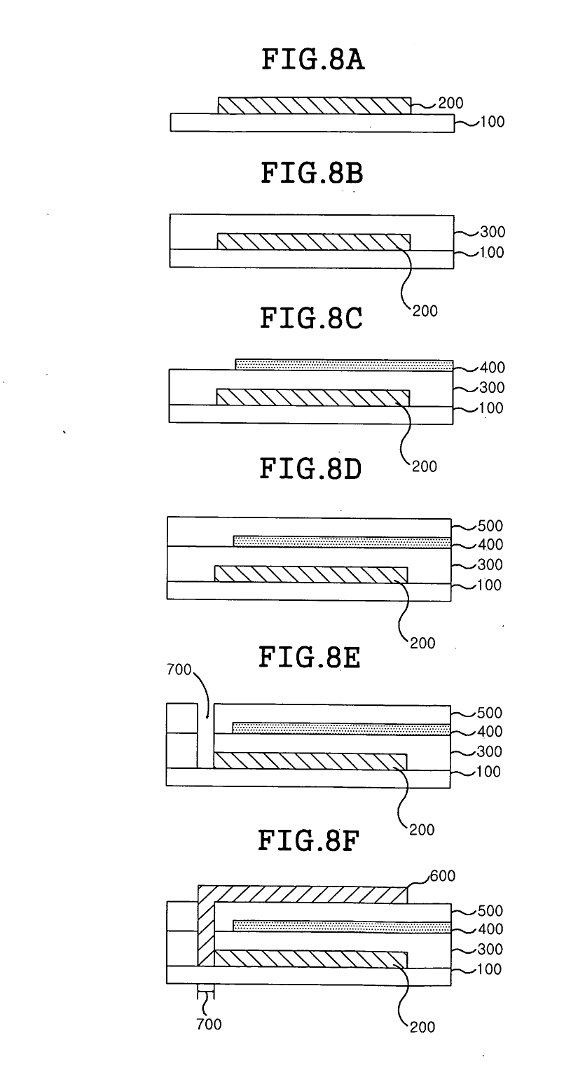

FIG. 8(A to F) is a series of cross section views illustrating a method for manufacturing a thin film type solar cell according to one embodiment of the present invention, which relates to the method for manufacturing the thin film type solar cell of FIG. 2(A).

First, as shown in FIG. 8(A), a first electrode 200 is formed in a predetermined pattern on a substrate 100.

A process for forming the front electrode 200 may comprise steps of depositing a transparent conductive material, for example, ZnO, ZnO:B, ZnO:Al, SnO₂, SnO₂:F, or ITO (Indium Tin Oxide), on an entire surface of the substrate 100 by sputtering or MOCVD (Metal Organic Chemical Vapor Deposition), and forming the first electrode 200 in the predetermined pattern by a laser-scribing method.

The process for forming the front electrode 200 may further comprise a step of forming an uneven surface of the first electrode 200, for example, an etching process using photolithography, an anisotropic etching process using a chemical solution, or a texturing process using a mechanical scribing.

Next, as shown in FIG. 8(B), a first semiconductor layer 300 is formed on the first electrode 200.

A process for forming the first semiconductor layer 300 may comprise a step of forming a silicon-based amorphous semiconductor material in a PIN structure by a plasma CVD method, wherein the PIN structure indicates a structure where a P-type semiconductor layer, an I-type semiconductor layer, and an N-type semiconductor layer are deposited in sequence.

As shown in FIG. 8(C), a second electrode 400 is formed in a predetermined pattern on the first semiconductor layer 300.

A process for forming the second electrode 400 may comprise steps of depositing a transparent conductive material, for example, ZnO, ZnO:B, ZnO:Al, SnO₂, SnO₂:F, or ITO (Indium Tin Oxide), on an entire surface of the first semiconductor layer 300 by sputtering or MOCVD (Metal Organic Chemical Vapor Deposition), and forming the second electrode 400 in the predetermined pattern by a laser-scribing method.

Next, as shown in FIG. 8(D), a second semiconductor layer 500 is formed on the second electrode 400.

A process for forming the second semiconductor layer 500 may comprise a step of forming a silicon-based amorphous semiconductor material, a microcrystalline semiconductor material, or an amorphous semiconductor/germanium material in an NIP structure by a plasma CVD method, wherein the NIP structure indicates a structure where the N-type semiconductor layer, the I-type semiconductor layer, and the P-type semiconductor layer are deposited in sequence.

As shown in FIG. 8(E), a contact via 700 is formed by removing predetermined portions from the first and second semiconductor layers 300 and 500.

A process for forming the contact via 700 may use a laser-scribing process. At this time, the contact via 700 is formed to expose the first electrode 200.

As shown in FIG. 8(F), a third electrode 600 of a predetermined pattern is electrically connected with the first electrode 200 through the contact via 700.

A process for forming the third electrode 600 may comprise steps of depositing a metal layer such as Ag, Al, Ag+Mo, Ag+Ni, or Ag+Cu by sputtering, and forming the third electrode 600 in the predetermined pattern by a laser-scribing method.

The third electrode 600 of the predetermined pattern may be directly formed by a simple method using a metal paste of Ag, Al, Ag+Mo, Ag+Ni, or Ag+Cu, through a screen printing method, an inkjet printing method, a gravure printing method, or a micro-contact printing method.

In the meantime, a transparent conductive layer may be deposited before forming the third electrode 600, to thereby manufacture the thin film type solar cell of FIG. 3(A). That is, after forming the contact via 700 as shown in FIG. 8(E), the transparent conductive material such as ZnO, ZnO:B, ZnO:Al, SnO₂, SnO₂:F, or ITO (Indium Tin Oxide) is deposited by sputtering or MOCVD; the metal material such as Ag, Al, Ag+Mo, Ag+Ni, or Ag+Cu is deposited by sputtering; and then the transparent conductive layer 650 and the third electrode 400 are simultaneously formed in the predetermined pattern by laser-scribing method, thereby manufacturing the thin film type solar cell of FIG. 3(A).

After forming the third electrode 600, an insulating layer 800 is formed on the third electrode 600, a fourth electrode 820 is formed on the insulating layer 800, a third semiconductor layer 840 is formed on the fourth electrode 820, and a fifth electrode 860 is formed on the third semiconductor layer 840, thereby manufacturing the thin film type solar cell of FIG. 5.

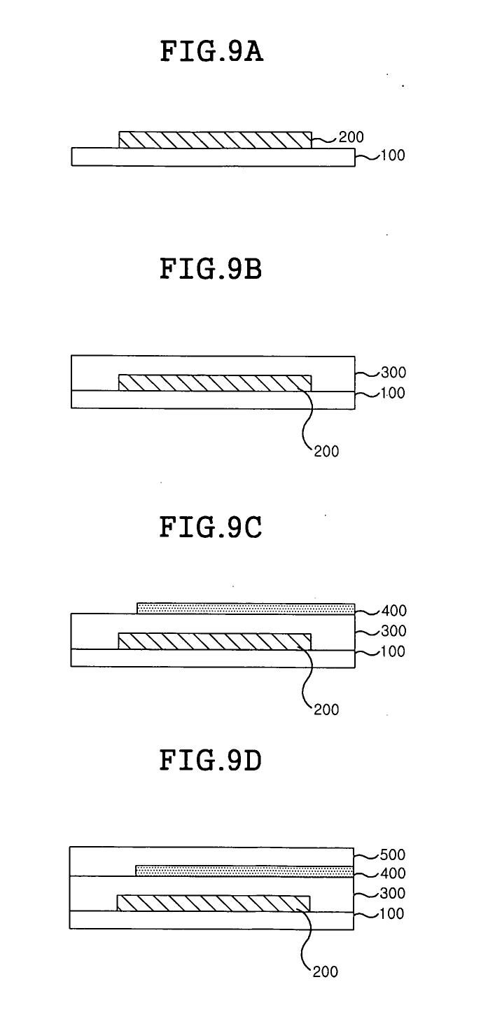

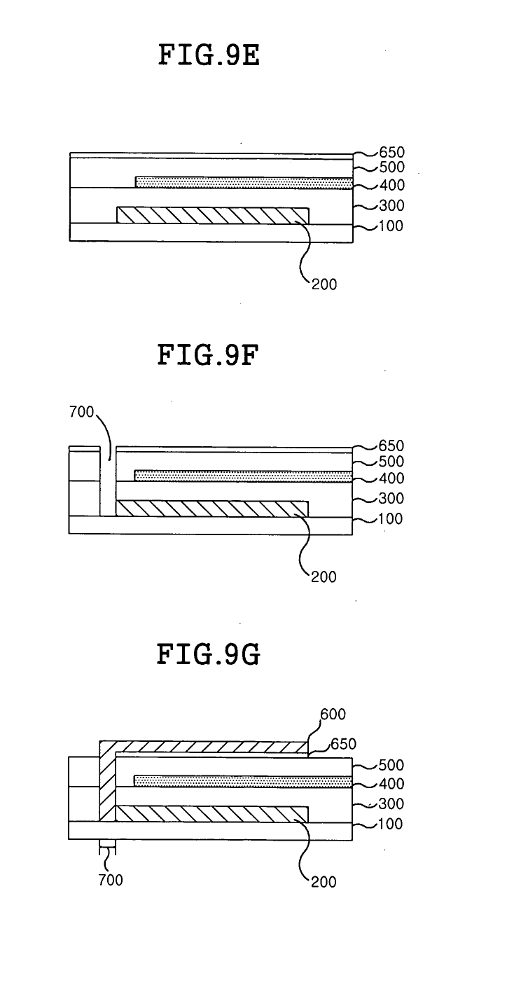

FIG. 9(A to G) is a series of cross section views illustrating a thin film type solar cell according to another embodiment of the present invention, which relates to the method for manufacturing the thin film type solar cell of FIG. 3(B). Hereinafter, a detailed explanation for the same parts as those of the aforementioned embodiment will be omitted.

First, as shown in FIG. 9(A), a first electrode 200 is formed in a predetermined pattern on a substrate 100.

Next, as shown in FIG. 9(B), a first semiconductor layer 300 is formed on the first electrode 200.

As shown in FIG. 9(C), a second electrode 400 is formed in a predetermined pattern on the first semiconductor layer 300.

As shown in FIG. 9(D), a second semiconductor layer 500 is formed on the second electrode 400.

As shown in FIG. 9(E), a transparent conductive layer 650 is deposited on the second semiconductor layer 500.

A process for depositing the transparent conductive layer 650 is carried out using a transparent conductive material, for example, ZnO, ZnO:B, ZnO:Al, SnO₂, SnO₂:F, or ITO (Indium Tin Oxide) by sputtering or MOCVD.

As shown in FIG. 9(F), a contact via 700 is formed by removing predetermined portions from the transparent conductive layer 650, the first semiconductor layer 300, and the second semiconductor layer 500.

As shown in FIG. 9(G), a third electrode 600 of a predetermined pattern is electrically connected with the first electrode 200 through the contact via 700.

A process for forming the third electrode 600 may comprise steps of depositing a metal material such as Ag, Al, Ag+Mo, Ag+Ni, or Ag+Cu by sputtering, and simultaneously forming the transparent conductive layer 650 and the third electrode 600 in the predetermined pattern by a laser-scribing method.

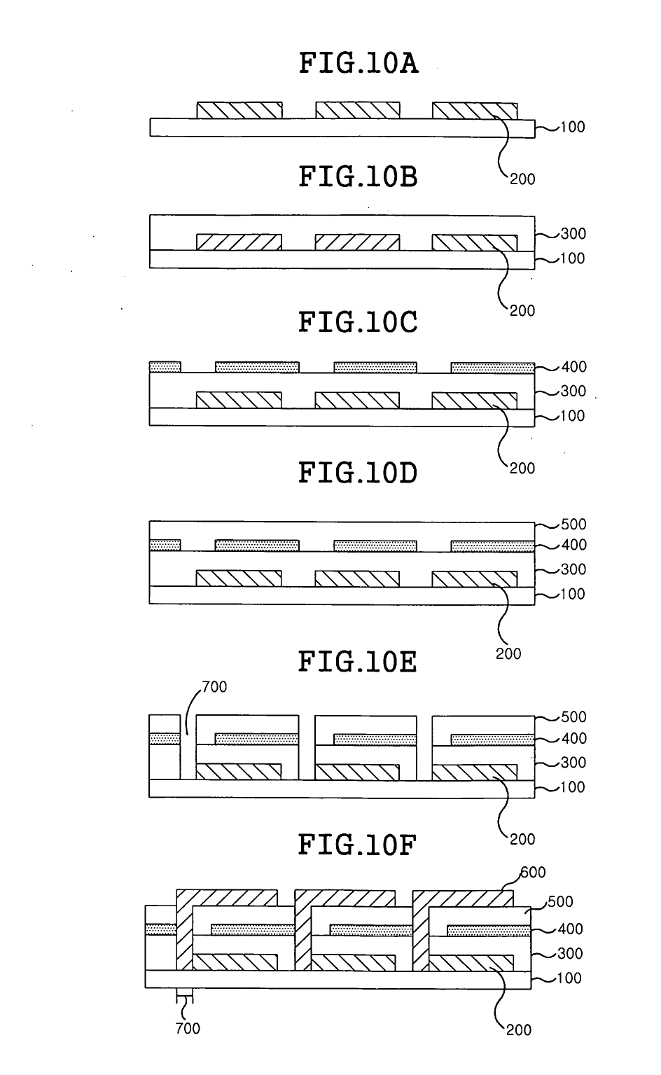

FIG. 10(A to F) is a series of cross section views illustrating a method for manufacturing a thin film type solar cell according to another embodiment of the present invention, which relates to the method for manufacturing the thin film type solar cell of FIG. 4(A). Hereinafter, a detailed explanation for the same parts as those of the aforementioned embodiment will be omitted.

First, as shown in FIG. 10(A), a plurality of first electrodes 200 are formed at fixed intervals on a substrate 100.

A process for forming the plurality of first electrodes 200 may comprise steps of depositing a first electrode layer on an entire surface of the substrate 100 by sputtering or MOCVD, and removing predetermined portions from the first electrode layer by a laser-scribing method.

As shown in FIG. 10(B), a first semiconductor layer 300 is formed on the first electrodes 200.

As shown in FIG. 10(C), a plurality of second electrodes 400 are formed at fixed intervals on the first semiconductor layer 300.

A process for forming the plurality of second electrodes 400 may comprise steps of depositing a second electrode layer on an entire surface of the first semiconductor layer 300 by sputtering or MOCVD, and removing predetermined portions from the second electrode layer by a laser-scribing method.

As shown in FIG. 10(D), a second semiconductor layer 500 is formed on the second electrodes 400.

As shown in FIG. 10(E), a contact via 700 is formed by removing predetermined portions from the first and second semiconductor layers 300 and 500.

As shown in FIG. 10(F), a plurality of third electrodes 600 are formed at fixed intervals. Each third electrode 600 is electrically connected with the first electrode 200 in the corresponding unit cell and the second electrode 400 in the neighboring unit cell through the contact via 700.

A process for forming the third electrodes 600 may comprise steps of depositing a third electrode layer on the entire surface of the substrate 100 including the contact via 700 by sputtering, and removing predetermined portions from the third electrode layer by a laser-scribing method.

When removing the predetermined portions from the third electrode layer by the laser-scribing method, predetermined portions of the second semiconductor layer, which are positioned underneath the third electrode layer, are also removed together, thereby resulting in a more definite division of the third electrode 600 by each unit cell.

Although not shown, a transparent conductive layer may be deposited before forming the third electrode 600, to thereby manufacture the thin film type solar cell including the transparent conductive layer formed under a lower surface of the third electrode 600. In order to manufacture the thin film type solar cell including the transparent conductive layer formed under the lower surface of the third electrode 600, the transparent conductive layer is deposited on the second semiconductor layer 500 before forming the contact via 700, and then the contact via 700 is formed thereafter, thereby manufacturing the thin film type solar cell which has no transparent conductive layer inside the contact via 700. A method for manufacturing the aforementioned thin film type solar cell with this structure can be easily understood with reference to the method for manufacturing the thin film type solar cell shown in FIG. 9(A to G).

After forming the third electrode 600, an insulating layer 800 is formed on the third electrode 600; a plurality of fourth electrodes 820 are formed at fixed intervals on the insulating layer 800; a third semiconductor layer 840 including a contact via 845 is formed on the fourth electrodes 820; and a fifth electrode 860 is formed on the third semiconductor layer 840, wherein the fifth electrode 860 is electrically connected with the neighboring fourth electrode 820 through the contact via 845, thereby manufacturing the thin film type solar cell of FIG. 6.

Also, after forming the third electrode 600, a third semiconductor layer 810 is formed on the third electrode 600; a plurality of fourth electrode 830 are formed at fixed intervals on the third semiconductor layer 810; a fourth semiconductor layer 850 is formed on the fourth electrodes 830; a contact via 700 is formed by removing predetermined portions from the third and fourth semiconductor layers 810 and 850; and a fifth electrode 870 in each unit cell is formed while being electrically connected with the third electrode 600 in the corresponding unit cell and the fourth electrode 830 in the neighboring unit cell through the contact via 700, thereby manufacturing the thin film type solar cell of FIG. 7.

As mentioned above, the thin film type solar cell according to the present invention and the method for manufacturing the same have the following advantages.

First, the first solar cell is composed of the combination of the first electrode, the first semiconductor layer of the PIN structure, and the second electrode; and the second solar cell is composed of the combination of the second electrode, the second semiconductor layer of the NIP structure, and the third electrode, wherein the first and second solar cells are connected in parallel. Thus, there is no requirement for the apparatus for the current matching between the first and second solar cells. In addition, the solar ray incident on the substrate is absorbed into the first and second solar cells, thereby resulting in the improved efficiency of the entire thin film type solar cell.

Also, the thin film type solar cell is divided into the plurality of unit cells, and the unit cells are connected in series. Thus, even though the substrate increases in size, it is possible to decrease the size of the electrode, thereby preventing the increase of electrode resistance. Accordingly, the efficiency of solar cell can be improved.

According as the transparent conductive layer is formed under the lower surface of the third electrode, the transparent conductive layer makes the solar ray dispersed in all angles, whereby the solar ray is reflected on the third electrode and is then re-incident on the solar cell, thereby resulting in the improved efficiency of solar cell.

Furthermore, the thin film type solar cell comprised of the first and second solar cells may be additionally provided with the third solar cell, or may be formed in the dual-layered structure, to thereby improve the efficiency of solar cell.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A thin film type solar cell comprising:
a first electrode in a predetermined pattern on a substrate;
a first semiconductor layer on the first electrode;
a second electrode in a predetermined pattern on the first semiconductor layer;
a second semiconductor layer on the second electrode; and
a third electrode in a predetermined pattern on the second semiconductor layer, wherein the first and third electrodes are electrically connected with each other.

2. The thin film type solar cell of claim 1, wherein a contact via is formed in predetermined portions of the first and second semiconductor layers, and the third electrode is connected with the first electrode through the contact via.

3. The thin film type solar cell of claim 1, further comprising:
an insulating layer on the third electrode;
a fourth electrode on the insulating layer;
a third semiconductor layer on the fourth electrode; and
a fifth electrode on the third semiconductor layer.

4. The thin film type solar cell of claim 1, wherein a transparent conductive layer is additionally formed under a lower surface of the third electrode.

5. The thin film type solar cell of claim 4, wherein the transparent conductive layer is formed inside the contact via.

6. The thin film type solar cell of claim 1, wherein the first semiconductor layer is formed in a PIN structure, and the second semiconductor layer is formed in an NIP structure; or
wherein the first semiconductor layer is formed in the NIP structure, and the second semiconductor layer is formed in the PIN structure.

7. A thin film type solar cell comprising:
a plurality of first electrodes at fixed intervals on a substrate;
a first semiconductor layer on the first electrodes;
a plurality of second electrodes at fixed intervals on the first semiconductor layer;
a second semiconductor layer on the second electrodes; and
a plurality of third electrodes at fixed intervals on the second semiconductor layer, wherein each first electrode corresponds to a second electrode and third electrode within a defined unit cell, and the third electrode in each unit cell is electrically connected with the first electrode in that same unit cell and to the second electrode in an adjacent unit cell.

8. The thin film type solar cell of claim 7, wherein a contact via is formed in predetermined portions of the first and second semiconductor layers, and the third electrode in each unit cell is connected with the first electrode in that same unit cell and to the second electrode in an adjacent unit cell through the contact via.

9. The thin film type solar cell of claim 7, further comprising:
an insulating layer on the third electrode;
a plurality of fourth electrodes at fixed intervals on the insulating layer;
a third semiconductor layer including a predetermined contact via on the fourth electrodes; and
a plurality of fifth electrodes at fixed intervals, wherein the fifth electrode is connected with the fourth electrode through the predetermined contact via.

10. The thin film type solar cell of claim 7, further comprising:
a third semiconductor layer on the third electrodes;
a plurality of fourth electrodes at fixed intervals on the third semiconductor layer;
a fourth semiconductor layer on the fourth electrodes; and
a plurality of fifth electrodes at fixed intervals on the fourth semiconductor layer, wherein a contact via is formed in predetermined portions of the third and fourth semiconductor layers, and the fifth electrode in each unit cell is connected with the third electrode in that same unit cell and to the fourth electrode in an adjacent unit cell through the contact via formed in the predetermined portions of the third and fourth semiconductor layers.

11. The thin film type solar cell of claim 7, wherein a transparent conductive layer is additionally formed under a lower surface of the third electrode.

12. The thin film type solar cell of claim 11, wherein the transparent conductive layer is formed inside the contact via.

13. The thin film type solar cell of claim 7, wherein the first semiconductor layer is formed in a PIN structure, and the second semiconductor layer is formed in an NIP structure; or
wherein the first semiconductor layer is formed in the NIP structure, and the second semiconductor layer is formed in the PIN structure.

14. A method for manufacturing a thin film type solar cell comprising:
forming a first electrode in a predetermined pattern on a substrate;
forming a first semiconductor layer on the first electrode;
forming a second electrode in a predetermined pattern on the first semiconductor layer;
forming a second semiconductor layer on the second electrode;
forming a contact via by removing predetermined portions from the first and second semiconductor layers; and
forming a third electrode in a predetermined pattern, wherein the third electrode is electrically connected with the first electrode through the contact via.

15. The method of claim 14, further comprising:
forming an insulating layer on the third electrode;
forming a fourth electrode on the insulating layer;
forming a third semiconductor layer on the fourth electrode; and
forming a fifth electrode on the third semiconductor layer.

16. The method of claim 14, further comprising depositing a transparent conductive layer on the second semiconductor layer before forming the contact via.

17. The method of claim 14, further comprising depositing a transparent conductive layer under a lower surface of the third electrode after forming the contact via.

18. The method of claim 14, wherein the step of forming the first semiconductor layer comprises forming a PIN structure, and the step of forming the second semiconductor layer comprises forming an NIP structure; or
wherein the step of forming the first semiconductor layer comprises forming the NIP structure, and the step of forming the second semiconductor layer comprises forming the PIN structure.

19. A method for manufacturing a thin film type solar cell comprising:
forming a plurality of first electrodes at fixed intervals on a substrate;
forming a first semiconductor layer on the first electrodes;
forming a plurality of second electrodes at fixed intervals on the first semiconductor layer;
forming a second semiconductor layer on the second electrodes;
forming a contact via by removing predetermined portions from the first and second semiconductor layers; and
forming a plurality of third electrodes at fixed intervals, wherein each first electrode corresponds to a second electrode and third electrode within a defined unit cell, and the third electrode in each unit cell is electrically connected with the first electrode in that same unit cell and to the second electrode in an adjacent unit cell through the contact via.

20. The method of claim 19, further comprising:
forming an insulating layer on the third electrodes;
forming a plurality of fourth electrodes at fixed intervals on the insulating layer;
-forming a third semiconductor layer including a predetermined contact via on the fourth electrodes; and
forming a plurality of fifth electrodes at fixed intervals, wherein the fifth electrode is connected with the fourth electrode through the predetermined contact via formed in the third semiconductor layer.

21. The method of claim 19, further comprising:
forming a third semiconductor layer on the third electrodes;
forming a plurality of fourth electrodes at fixed intervals on the third semiconductor layer;
forming a fourth semiconductor layer on the fourth electrodes;
forming a contact via by removing predetermined portions from the third and fourth semiconductor layers; and
forming a plurality of fifth electrodes at fixed intervals within said unit cells, wherein the fifth electrode in each unit cell is electrically connected with the third electrode in that same unit cell and to the fourth electrode in an adjacent unit cell through the contact via formed by removing the predetermined portions from the third and fourth semiconductor layers.

22. The method of claim 19, further comprising depositing a transparent conductive layer on the second semiconductor layer before forming the contact via.

23. The method of claim 19, further comprising depositing a transparent conductive layer under a lower surface of the third electrode after forming the contact via.

24. The method of claim 19, wherein the step of forming the plurality of third electrodes is comprised of:
forming a third electrode layer on an entire surface of the substrate including the contact via; and
removing a predetermined portion of the third electrode layer.

25. The method of claim 24, wherein the step of removing the predetermined portion of the third electrode layer comprises removing a predetermined portion of the second semiconductor layer underneath the third electrode layer.

26. The method of claim 19, wherein the step of forming the first semiconductor layer comprises forming a PIN structure, and the step of forming the second semiconductor layer comprises forming an NIP structure; or
wherein the step of forming the first semiconductor layer comprises forming the NIP structure, and the step of forming the second semiconductor layer comprises forming the PIN structure.
